(19) United States
(12) Patent Application Publication
(10) Pub. No.: US 2009/0258472 A1
(43) Pub. Date: Oct. 15, 2009

(54) Semiconductor array and method for manufacturing a semiconductor array

(75) Inventors: Tobias Florian, Stuttgart (DE); Michael Graf, Leutenbach (DE); Stefan Schwantes, Heilbronn (DE)

Correspondence Address: Muncy, Geissler, Olds & Lowe, PLLC, P.O. BOX 1364, FAIRFAX, VA, 22038-1364, US

(73) Assignee: ATMEL Germany GmbH, Heilbronn (DE)

(21) Appl. No.: 11/528,400

(22) Filed: Sep. 28, 2006

(30) Foreign Application Priority Data
Sep. 29, 2005 (DE) 10 2005 046 624.9

(51) Int. Cl. H01L 21/762

(52) U.S. Cl. 438/424; 438/675; 257/E21.546

(57) ABSTRACT

Method for manufacturing a semiconductor array, in which
a conductive substrate (100), a component region (400), and an insulation layer (200), isolating the component region (400) from the conductive substrate (100), are formed,
a trench (700) is etched in the component region (400) as far as the insulation layer (200),
then the trench (700) is etched further as far as the conductive substrate (100),
the walls (701) of the trench (700) are formed with an insulation material (710), and
an electrical conductor (750, 755, 760) is introduced into the trench (700) and connected conductively to the conductive substrate (100),
   wherein
before the trench (700) is etched, a layer sequence comprising a first oxide layer (510), a polysilicon layer (520) on top of the first oxide layer (510), and a second oxide layer (530) on top of the polysilicon layer (520) is applied to the component region (400).

The present invention relates to a semiconductor array, a circuit, and a method for manufacturing a semiconductor array.

A method for manufacturing a semiconductor component is known from German Patent DE 102 60 616 B3. In this case, a component structure is formed on a wafer, whereby the wafer comprises a backside semiconductor substrate, a buried insulation layer, and a top semiconductor layer. An etch stop layer is formed on the wafer. The wafer carries the component structure. A window is formed in the etch stop layer. A dielectric layer is formed on the etch stop layer, which has a window formed therein. This is followed by simultaneous etching of a first contact hole through the dielectric layer and the window down to the backside semiconductor substrate and at least one second contact hole through the dielectric layer down to the component structure.

In the manufacturing of semiconductor components, SOI wafers or substrates are used to provide superior isolation between adjacent components in an integrated circuit as compared to components built into bulk wafers. SOI substrates are silicon wafers with a thin layer of oxide or other insulators buried therein. Components are built into a thin layer of silicon on top of the buried oxide. The superior isolation thus achieved may eliminate the “latch-up” in CMOS components (CMOS: Complementary Metal Oxide Semiconductor) and further reduces parasitic capacitances. In addition to the buried oxide layer, shallow trench isolation (STI) is often used to completely isolate transistors or other components from each other.

Because the backside silicon substrate is completely decoupled from the components by means of the buried oxide, the potential of the backside substrate tends to float during the operation of the circuit. This may influence the properties of the circuit and reduce operation reliability.

To prevent the backside silicon substrate of the component from floating, special contacts are formed to connect the backside substrate to a metal layer that has a defined potential. An SOI structure is used first that comprises a backside silicon substrate, a buried oxide layer, and a top silicon layer. Transistor structures are formed on top of the SOI structure. The top silicon layer has etched isolation trenches, filled with STI material, to decouple the transistor structures from each other and from other components.

On top of the top silicon layer, the STI material of the isolation trenches, and the transistor structures, for example, a silicon oxynitride (SiON) layer is deposited that is used in subsequent etching processes as a stop layer. Further, silicides may be formed between this etch stop layer and the top silicon layer.

Further, a TEOS (tetraethylorthosilicate) layer is deposited as a masking layer. Then, after the transistor structures and the contact stack of silicon oxynitride (SiON) and tetraethylorthosilicate (TEOS) are formed, a photoresist layer is patterned to provide a backside contact mask having an opening for etching a contact to the backside silicon substrate.

Once the backside contact mask pattern is defined in the photoresist layer, the stack of tetraethylorthosilicate (TEOS), silicon oxynitride (SiON), STI material, and buried oxide is etched down to the backside silicon substrate. A contact hole is formed by this etching step. The STI material of the isolation trench is divided by the formation of the contact hole. The photoresist is now removed by a plasma strip and an additional wet chemical cleaning step.

Once the backside contact hole has been formed, the formation of contacts to connect the transistor structures takes place. This will require another photoresist layer pattern process and a separate etching step.

The aforementioned prior art can be derived, for example, from the Unexamined German Patent Application DE 100 54 109 A1. In addition, reference is made to U.S. Pat. No. 5,965,917 A, which also deals with the problems of substrate contacting in SOI structures. Two conductive substrate layers, isolated from one another by a buried oxide layer, as conductive rails, each of which are contacted by a deep trench, are known from the U.S. Patent Application No. 2003/0094654 A1.

A through-hole plating through a buried insulation layer in a semiconductor substrate is known from European Patent EP 1 120 835 A2. In this case, the through-hole plating connects the source region of a field effect transistor with the semiconductor substrate formed under the buried insulation layer. A method for producing substrate contacts in SOI circuit structures is also known from German Patent DE 103 03 643 B3. In this case, several layer sequences of overlapping metallization layers are formed in the area of the contacting. On the other hand, a contacting of a silicon substrate in a doped region by means of polysilicon is disclosed in WO 02/073667 A2.

Contacting of a substrate region through a dielectric layer is known from U.S. Pat. No. 6,372,562 B1, whereby the contacted substrate region is isolated from another substrate region by a p-n junction poled in the blocking direction. The U.K. Patent Application No. GB 2 346 260 A also discloses a method for forming a contact to a substrate region isolated by a p-n junction in a deep trench of an SOI component. A method for producing a trench in a substrate and its use in smart power technology is known from EP 0 635 884 A1. In this case, after reinforcing a trench mask by means of a non-conformally deposited protective layer, the buried insulation layer is etched as far as the silicon substrate in a second trench etching. Another method for producing substrate contacting is known from U.S. Pat. No. 6,632,710 B2.

The invention has as its object the further development of a method for producing a contacting of a conductive substrate.

This object is achieved according to the invention by means of a method with the features of claim 1. Preferred further embodiments of the invention are the subject of dependent claims.

Accordingly, a method for manufacturing a semiconductor array is provided. In this method, a conductive substrate, a component region, and an insulation layer, isolating the component region from the conductive substrate, are formed. This type of structure is also called an SOI structure (Silicon-On-Insulator). The component region preferably has a single-crystal semiconductor to form the semiconductor components.

A trench is etched in the component region as far as the insulation layer through the semiconductor material of the component region. In this case, the etching occurs preferably selectively in regard to oxide layers. Furthermore, it is preferable to use an etching that enables a high depth-to-width aspect ratio for the etching.

The deep trench is then etched as far as the conductive substrate. This etching step occurs preferably selectively in regard to semiconductor layers. The walls of the trench are formed next with an insulation material. To form the insulation material, for example, an oxide can be deposited on the wall regions of the trench. Preferably, to form the insulation material, however, a silicon area, adjacent to the trench, of the component region is oxidized. Preferably, in this case, the insulation material is adjacent to the buried insulation layer.

After the etching steps, preferably, an electrical conductor is introduced into the trench isolated by the insulation material from the semiconductor material of the component region. In this case, the electrical conductor is preferably connected conductively to the conductive substrate.

Before the trench is etched, a layer sequence comprising a first oxide layer, a polysilicon layer on top of the first oxide layer, and a second oxide layer on top of the polysilicon layer is applied to the component region. As masking, the layer sequence is to protect a surface region outside the deep trench to be etched from etching attacks.

A preferred embodiment provides that the layer sequence is patterned lithographically in such a way that a vertical opening is introduced into the layer sequence, whereby the trench is etched deeply through this vertical opening. The opening is thereby preferably positioned in a recess in a surface of the component region in order to align the opening to the component region. For lithographic patterning, for example, a photoresist known per se can be applied and exposed with a mask. The opening is then etched into the layer sequence.

In another advantageous development variant of the invention, the second oxide layer is etched simultaneously with the buried insulation layer exposed in the trench. The etching is therefore stopped at or in the polysilicon layer and also at or in the semiconductor material of the substrate.

In another advantageous development variant of the invention, it is provided that the polysilicon layer is oxidized in the step for forming the insulation material and thereby reinforces the first oxide layer in its thickness. In this regard, it is preferably also provided that an oxide layer is formed on the bottom of the trench. The oxidized polysilicon layer together with the first oxide layer forms a silicon dioxide top layer, which is thicker than the oxide layer covering the bottom. Advantageously, in a subsequent etching of the oxide layer, covering the bottom, the silicon dioxide top layer is not completely removed, so that it remains thinned as an insulation layer.

Furthermore, it is preferably provided that for conductive connection of the electrical conductor to the conductive substrate, the insulation material, covering the bottom of the trench, is removed. For removal, this oxide layer covering the bottom is removed substantially in the vertical direction by means of a plasma etching step (ICP, inductive coupled plasma). However, the insulation material on the sidewalls of the deep trench is retained for purposes of isolation. Preferably, to form the insulation material, a silicon region, adjacent to the trench, of the component region is therefore oxidized to an oxide layer.

In an advantageous development variant of the invention, it is provided that a plurality of components in the component region are formed after the formation of the insulation material. The thermal budget for forming the components in the component region can therefore occur independent of the formation of the deep trenches. If a conductor of polysilicon is introduced into the deep trench, this can also occur advantageously before the formation of the semiconductor components. The majority of the components are thereby isolated from one or more substrate regions in the vertical direction by the buried insulator layer. Furthermore, the insulation material in the deep trenches makes possible a lateral isolation of at least two components.

Preferably to improve the invention further, an isolation trench is etched concurrently with the etching of the trench for receiving the conductor, whereby the isolation trench is completely filled with an insulator and serves exclusively to isolate a component. This makes it possible to reduce the number of necessary etching steps, particularly in the semiconductor material of the component region. Moreover, the positioning accuracy of the deep trench for the conductor for contacting of the substrate and of the additional deep trenches relative to each other is improved.

Advantageous embodiments of the invention provide that highly doped semiconductor material and/or metal and/or silicide is introduced for the electrical conductor.

According to another advantageous development variant, the trench is formed within a recess in a surface. In this case, the first oxide layer, the polysilicon layer, and the second oxide layer are applied in the recess. The recess can be formed, for example, as a shallow trench (STI, Shallow Trench Isolation).

According to another advantageous development variant, the conductive substrate is formed with a number of substrate regions isolated from one another. These substrate regions can be separated from one another, for example, by deep trench etching. Preferably, these deep trenches are then filled with a dielectric. A separate, fixed or variable potential can thereby be applied to each substrate region independently from one another, so that separate components in the component region can be operated with different applied substrate potentials. It is preferably provided here that the substrate regions, isolated from one another, are conductively connected each with at least one electrical conductor disposed in a trench. In addition, a non-contacted substrate region can also be formed.

Another aspect of the invention is the use of a previously described method for the manufacture of a circuit. This circuit has means for applying a constant or controllable potential to the electrical conductor of the semiconductor array. In this case, at least one electrical property of the component depends on the constant or controllable potential.

Furthermore, a subject of the invention is a semiconductor array, which is manufactured by means of the previously explained method. Said semiconductor array has a component region, a conductive substrate, and a buried insulation layer, whereby the insulation layer isolates the component region from the conductive substrate. The semiconductor array has at least one trench, which is filled with an insulation material and which isolates at least one component in the component region from other components in the component region. An electrical conductor is conductively connected to the conductive substrate. The electrical conductor is disposed isolated by the insulation material within the trench. Preferably, the trench is thereby made within a recess in the surface.

The contacting of the conductive substrate can have different functions. An important function is to change the component parameters of components disposed on the opposite side of the buried insulation layer by the amount or the time course of the applied substrate potential. In particular, the breakdown voltage of a lateral N-DMOS transistor can be improved. Furthermore, a current gain of an NPN-bipolar transistor can be changed, particularly increased, by the amount of an applied substrate potential. It is possible to achieve considerable improvement for positive substrate potentials in this way. Furthermore, the substrate may be used in addition as a line connection to another component or to an integrated circuit contact disposed on the backside. It is also possible by introducing dopants into the substrate, to form semiconductor components, such as, for example, diodes in the substrate.

Another aspect of the invention is a circuit with an aforementioned semiconductor array. This semiconductor array has [text missing] electrical conductor . . . a constant or controllable potential is applied, on which at least one electrical property of the component is dependent.

The previously described development variants and embodiments are especially advantageous both individually and in combination. In this regard, all development variants and/or embodiments can be combined with one another. A possible combination is explained in the description of the exemplary embodiment in the figures. This possible combination, described therein, of development variants and embodiments is not definitive, however.

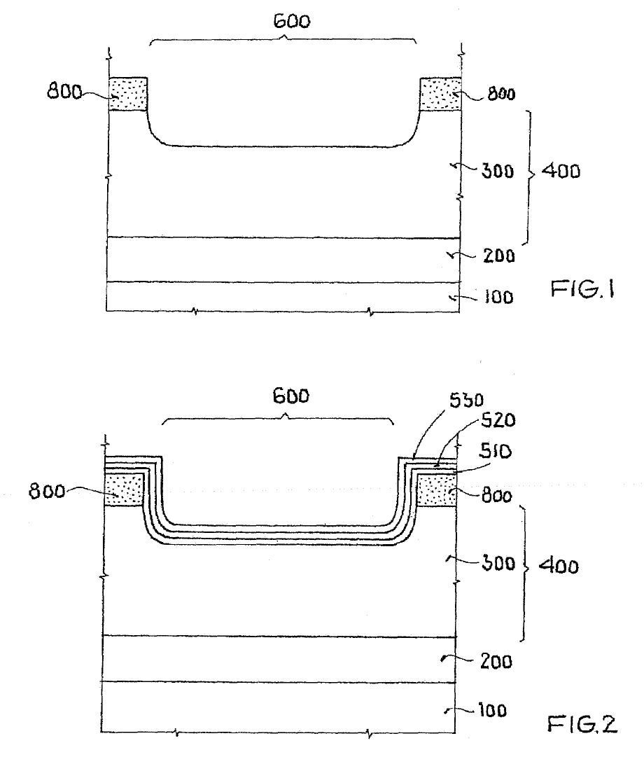

In the following text, the invention will be illustrated in greater detail in an exemplary embodiment using a drawing with FIGS. 1 through 8.

Here, the figures show:

FIG. 1 to FIG. 7 schematic sectional views through a wafer at different time points in the process for manufacturing a semiconductor array, and

FIG. 8 a schematic sectional view of an LDMOS field-effect transistor with a connection to the substrate.

Schematic sectional views through a wafer at different time points in the process for manufacturing a semiconductor array are shown in FIGS. 1 through 8. The same structural elements are usually provided with the same reference characters.

A component region 400 made of silicon 300 as the semiconductor material, a conductive, n-doped silicon substrate 100, and a buried insulation layer 200 are shown in FIG. 1. Insulation layer 200 isolates component region 400 from silicon substrate 100. Insulation layer 200 is a dielectric, for example, made of silicon dioxide (SiO₂). A hard mask 800 of silicon nitride (Si₃N₄) is applied to silicon 300 of component region 400 for masking. A shallow trench 600 (STI) is etched into silicon 300, whereby regions for forming components are protected by hard mask 800 from the etching attack.

In FIG. 2, a layer sequence comprising a first silicon dioxide layer 510 (SiO₂), a layer of polycrystalline silicon 520 (poly-Si), and a second silicon dioxide layer 530 (SiO₂) is applied within etched trench 600 and on hard mask 800. This layer sequence 510, 520, 530 is also called an OPO layer. Preferably, these layers 510, 520, 530 are deposited successively one after another.

The layer sequence of layers 510, 520, 530 is patterned lithographically by a photoresist and a mask in such a way that a vertical opening is introduced into the layer sequence. In this case, first the second oxide layer, next the polycrystalline silicon layer, and then the first oxide layer are etched through a resist opening in the photoresist masking. A deep trench 700 (Deep Trench) in semiconductor material 300 of component region 400 is etched through this vertical opening in the stack. This etching is selective in regard to second oxide layer 530 and thereby substantially removes only silicon 300 as far as buried insulation layer 200. After this, buried oxide 200 is removed below the etched opening. At the same time, second oxide layer 530 is also removed. FIG. 3 shows the state after the etching of the second oxide layer and of buried oxide 200 below the etched opening. Deep trench 700 has trench walls 701 and a trench bottom 702.

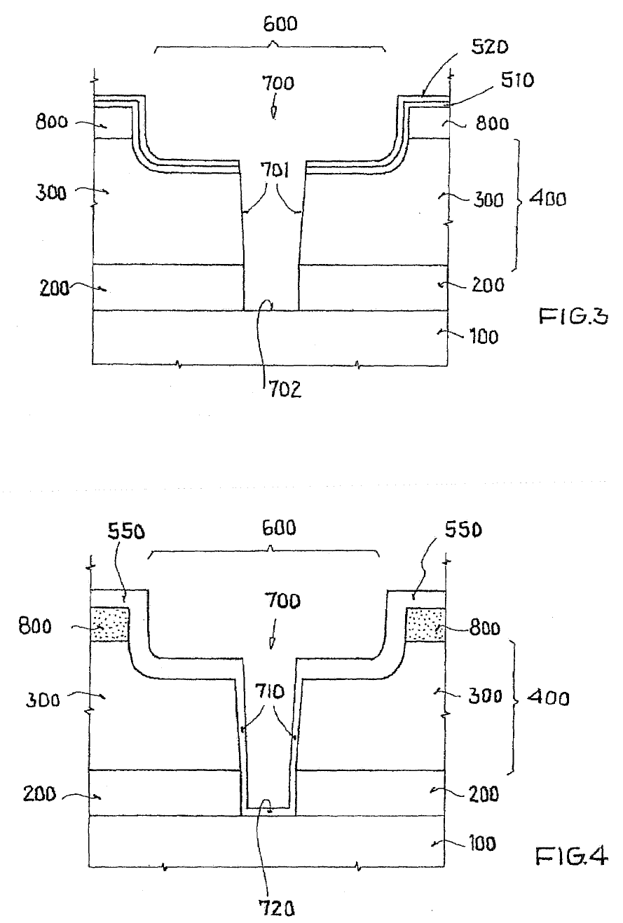

Subsequently, in the next process step, a thermal oxide of high quality is produced, preferably with a thickness of 50 nm. In this case, an oxide layer 710 or 720, respectively, is formed at trench walls 701 and on trench bottom 702. This state is shown schematically in FIG. 4. In this case, the silicon material of component region 400 in the wall region and the silicon material of silicon substrate 100 are converted to silicon dioxide. Furthermore, polysilicon layer 520 is also converted to silicon dioxide, so that together with first oxide layer 510 a silicon dioxide top layer 550 is formed, which is thicker than oxide layer 720 on bottom 702 of trench 700.

In the next process step, oxide 720 on the bottom of deep trench 700 is etched off by anisotropic etching. This process state is shown in FIG. 5. In this case, silicon dioxide top layer 550′ is accordingly thinned, but remains as an insulator. This also applies to oxide layer 710 at walls 701 of trench 700, which is also merely thinned and remains as an insulator.

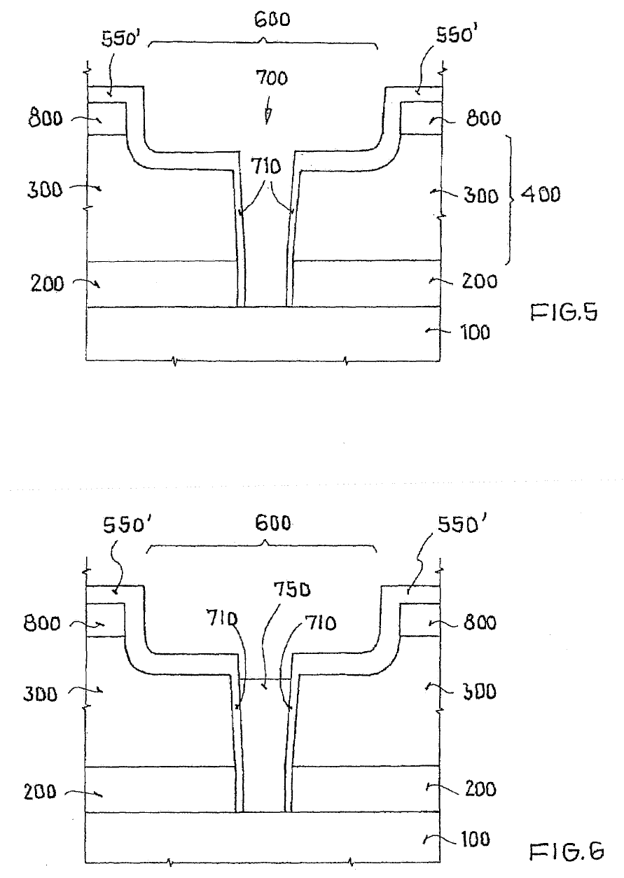

Then, conformal polysilicon 750 or amorphous silicon 750 is deposited on the wafer and etched back to the entrance of deep trench 700. This state is shown in FIG. 6. Polysilicon 750 can either be already doped during the deposition or in the later contact opening by implantation. The doping type advantageously corresponds to that of silicon substrate 100.

Next, shallow trench 600 is filled with oxide 580, the hard mask (800) is removed, and the wafer surface is planarized, for example, by means of chemical mechanical polishing (CMP). The next process steps are used to produce the semiconductor components in component region 400. The contacting of silicon substrate 100 through deep trench 700 (contact trench) is continued only after all components are finalized.

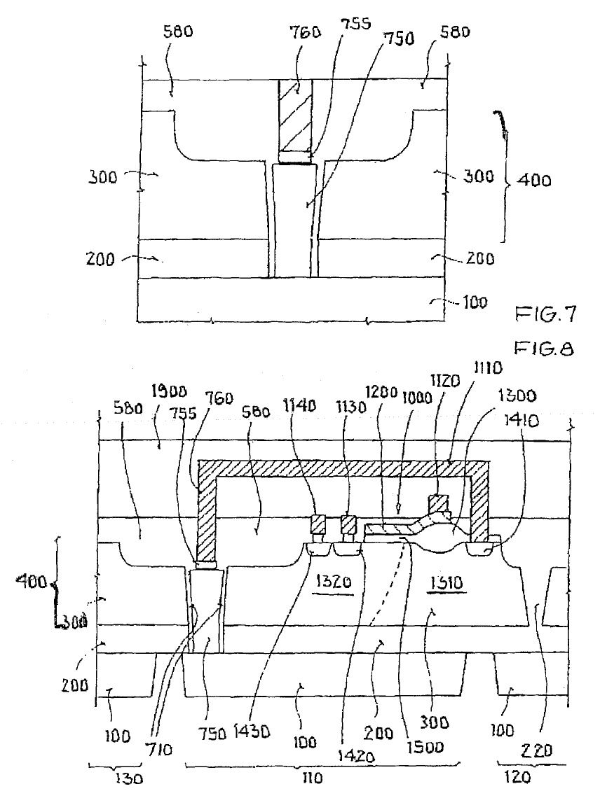

For contacting polysilicon filling 750, oxide 580 in shallow trench 600 is removed above polysilicon 750 in a lithographic masked etching step. The etched oxide opening is now filled with a diffusion barrier 755, for example, made of a silicide, and with a metal 760, for example, tungsten. This process state is shown in FIG. 7.

FIG. 8 shows a schematic sectional view through a wafer with a power component 1000, which is formed in component region 400, and a contacting of silicon substrate 100. Silicon substrate 100 is thereby divided into several substrate regions 110, 120, 130 by etched trenches. A substrate region 110 is thereby formed below power component 1000. Power component 1000 is isolated by the deep trench (700), filled with polysilicon 750, and by at least one other trench isolation 220 from neighboring components (not shown in FIG. 8) by a dielectric 710, 220, particularly of silicon dioxide.

In the exemplary embodiment of FIG. 8, power component 1000 is an N-DMOS field-effect transistor 1000. This has an n-doped drain semiconductor region 1410, an N-well 1310, formed as a drift zone, a P-well 1320, formed as a body semiconductor region, an n-doped source semiconductor region 1420, and a p-doped body terminal semiconductor region 1430. Furthermore, N-DMOS field-effect transistor 1000 has a field-oxide 1300 and a gate oxide 1500 with polysilicon gate electrode 1200 disposed thereon. Drain semiconductor region 1410, gate electrode 1200, source semiconductor region 1420, and body terminal semiconductor region 1430 are each conductively connected to a metal trace 1110, 1120, 1130, and 1140. In the exemplary embodiment of FIG. 8, substrate region 110 is connected via polysilicon 750, diffusion barrier 755, metal 760, and trace 1110 to drain semiconductor region 1410, so that substrate region 110 substantially has the same potential as drain semiconductor region 1410. The wafer is protected from outside influences by a boron-phosphorus-silicate glass 1900.

Alternatively to FIG. 8, substrate region 110 can also be connected to another component for controlling the potential of substrate region 110. Another possibility is to connect substrate region 110, for example, by means of a voltage divider comprising two capacitors, to a fixed potential.

The invention is understandably not limited to the shown exemplary embodiment, but also comprises embodiment variants that are not shown. For example, the aspect ratio for shallow trench 600 and deep trench 700, as shown in the exemplary embodiment, can also be made different. It is also possible to use a metallic substrate. The invention is also not limited to the power component 1000 shown in FIG. 2. It also protects every method that makes use of the OPO layer sequence 510, 520, 530 for patterning the deep trench 700 and in dual function for isolation of the shallow trench 600 in particular.

### List of Reference Characters

100 Silicon substrate
110, 120, 130 Substrate region
200 Buried insulation layer, SiO₂
220 Deep trench filled with dielectric
300 Single-crystal silicon crystal
400 Component region
510 First oxide layer
520 Polysilicon layer
530 Second oxide layer
550, 550′ Oxide layer
580 Dielectric, silicon dioxide
600 Shallow, etched trench
700 Deep trench, etched
701 Wall of the deep trench
702 Bottom of the deep trench
710 Insulation material, silicon dioxide
720 Insulation material, silicon dioxide
750 Doped polysilicon filling
755 Diffusion barrier, silicide
760 Metal, tungsten, aluminum
800 Hard mask, Si₃N₄
1000 Component, N-DMOS field-effect transistor
1110, 1120, Metallization, trace
1130, 1140
1200 Gate electrode, polycrystalline silicon
1300 Field oxide
1310 N-well, drift zone
1320 P-well, body
1410 Drain semiconductor region
1420 Source semiconductor region
1430 Body terminal semiconductor region
1500 Gate oxide
1900 Boron-phosphorus-silicate glass

1. Method for manufacturing a semiconductor array, wherein
a conductive substrate, a component region, and an insulation layer, isolating the component region from the conductive substrate, are formed,
a trench is etched in the component region as far as the insulation layer,
then the trench is etched further as far as the conductive substrate,
the walls of the trench are formed with an insulation material, and
an electrical conductor is introduced into the trench and connected conductively to the conductive substrate, wherein before the trench is etched, a layer sequence comprising a first oxide layer, a polysilicon layer on top of the first oxide layer, and a second oxide layer on top of the polysilicon layer is applied to the component region.

2. Method according to claim 1, wherein the layer sequence is patterned lithographically in such a way that a vertical opening is introduced into the layer sequence, wherein the trench is etched deeply through this vertical opening.

3. Method according to claim 1, wherein the second oxide layer is etched simultaneously with the buried insulation layers exposed in the trench.

4. Method according to claim 1, wherein the polysilicon layer is oxidized in the step for forming the insulation material.

5. Method according to claim 4, wherein an oxide layer is formed on the bottom of the trench, and in which the oxidized polysilicon layer together with the first oxide layer forms a silicon dioxide top layer, which is thicker than the oxide layer covering the bottom.

6. Method according to claim 5, wherein for conductive connection of the electrical conductor to the conductive substrate, the oxide layer, covering the bottom of the trench, is removed.

7. Method according to claim 4, wherein to form the insulation material, a silicon region, adjacent to the trench, of the component region is oxidized to an oxide layer.

8. Method according to claim 4, in wherein a plurality of components in the component region are formed after the formation of the insulation material.

9. Method according to claim 4, wherein an insulation trench is etched concurrently with the etching of the trench for receiving the conductor, wherein the isolation trench is preferably completely filled with an insulator and serves exclusively to isolate the component.

10. Method according to claim 4, wherein highly doped semiconductor material and/or metal and/or silicide is introduced for the electrical conductor.

11. Method according to claim 4, in which the trench is formed within a recess in a surface, whereby the first oxide layer, the polysilicon layer, and the second oxide layer are applied in the recess.

12. Use of a method according to claim 4 for the manufacture of a circuit, which has means for applying a constant or controllable potential at the electrical conductor of the semiconductor array, wherein at least one electrical property of the component depends on the constant or controllable potential.
